(19) United States
(12) Patent Application Publication
(10) Pub. No.: US 2018/0213687 A1
(43) Pub. Date: Jul. 26, 2018

(54) POWER SUPPLY APPARATUS

(71) Applicant: FSP Technology Inc., Taoyuan City (TW)

(72) Inventors: Po-Chang Lu, Taoyuan City (TW); Wun-Liang Luo, Taoyuan City (TW)

(73) Assignee: FSP TECHNOLOGY INC., Taoyuan City (TW)

(21) Appl. No.: 15/878,424

(22) Filed: Jan. 24, 2018

(30) Foreign Application Priority Data
Jan. 25, 2017 (TW) 106201419
Sep. 5, 2017 (TW) 106130266

(51) Int. Cl. H05K 7/20

(52) U.S. Cl. CPC H05K 7/20927; H05K 7/20145; H05K 7/20272; H05K 7/20254

(57) ABSTRACT

A power supply apparatus includes a case, a circuit board, at least one heating element, and at least one internal liquid cooling heat-dissipation structure. The heating element is disposed in the case and electrically connected to the circuit board. The internal liquid cooling heat-dissipation structure is disposed in the case and located in at least one of manners which include being located between the case and the circuit board and being located between the case and the heating element. The internal liquid cooling heat-dissipation structure includes a tank and a heat conducting sheet. The tank includes an internal pipe. A working fluid is adapted to be filled in the internal pipe. The heat conducting sheet is assembled to the tank. The heat generated by the heat element is transmitted to the tank through the heat conducting sheet and dissipated by the working fluid circulating in the internal pipe.

### CROSS-REFERENCE TO RELATED APPLICATION

This application claims the priority benefits of Taiwan application serial no. 106201419, filed on Jan. 25, 2017, and Taiwan application serial no. 106130266, filed on Sep. 5, 2017. The entirety of each of the above-mentioned patent applications is hereby incorporated by reference herein and made a part of this specification.

### BACKGROUND

### Field of the Invention

The invention relates to a power supply apparatus and more particularly, to a power supply apparatus with a favorable heat dissipation effect.

### Description of Related Art

Generally, the heat from the internal of a power supply apparatus is dissipated mainly in a fan-cooling dissipation manner. In the fan-cooling dissipation manner, elements (for example, passive devices and semiconductor devices) capable of generating the heat contact a metal dissipation block, and the heat from is dissipated from the metal dissipation block is dissipated through fans. However, the increase in output power of the power supply apparatus causes increase in an internal temperature. For example, for a power supply apparatus having output power more than 1000 watts, an air flow of the fans also have to be increased, such that the additional waste heat can be exhausted out of the power apparatus through the strong air flow. A method for increasing the air flow includes nothing but increasing the rotation speed or the number of the fans. Nevertheless, when the rotation speed of the fans is increased, or multiple fans operate simultaneously, issues, such as high noise, high vibration and high power consumption, usually occur, which influence overall efficiency of the power supply apparatus and cause discomfort to users.

In order to solve the aforementioned issues, a current power supply apparatus adopts a liquid-cooling dissipation manner in replacement for the conventional fan-cooling dissipation manner. However, in the recent liquid-cooling dissipation manner, internal liquid-cooling dissipation pipes are mainly disposed in a case of the power supply apparatus, wherein all the internal liquid-cooling dissipation pipes have to be made of a metal material and directly contact the heating elements for effectively dissipating the heat. Thus, the internal liquid-cooling dissipation pipes, when contacting primary-side heating elements and secondary-side heating elements of the circuit, is subject to the occurrence of arc discharge between the primary-side heating elements and the secondary-side heating elements and therefore, may tend to safety concerns. Additionally, the disposition of the internal liquid-cooling dissipation pipes also requires to be arranged together with a circuit design and the disposition of the internal elements of the case, which relatively lacks use flexibility and may not be adapted for all types of power supply apparatuses.

### SUMMARY

The invention provides a power supply apparatus which can achieve a favorable heat dissipation effect and avoid the occurrence of high noise.

A power supply apparatus of the invention includes a case, a circuit board, at least one heating element and at least one internal liquid cooling heat-dissipation structure. The circuit board is disposed in the case. The heating element is disposed in the case and electrically connected to the circuit board. The internal liquid cooling heat-dissipation structure is disposed in the case and located in at least one of manners which include being located between the case and the circuit board and being between the case and the heating element. The internal liquid cooling heat-dissipation structure includes a tank and a heat conducting sheet. The tank includes an internal pipe, wherein a working fluid is adapted to be filled in the internal pipe. The heat conducting sheet is assembled to the tank, wherein the heat generated by the heating element is transmitted to the tank through the heat conducting sheet and is dissipated by the working fluid circulating in the internal pipe.

In an embodiment of the invention, the power supply apparatus further includes at least one insulating and heat conducting structure disposed in the case and located in at least one of manners which include being located between the circuit board and the internal liquid cooling heat-dissipation structure and being located between the heating element and the internal liquid cooling heat-dissipation structure.

In an embodiment of the invention, the internal liquid cooling heat-dissipation structure is located between the case and the circuit board, the insulating and heat conducting structure is located between the circuit board and the internal liquid cooling heat-dissipation structure, and two opposite surfaces of the insulating and heat conducting structure directly contact the circuit board and heat conducting sheet, respectively.

In an embodiment of the invention, the internal liquid cooling heat-dissipation structure is located between the case and the heating element, the insulating and heat conducting structure is located between the heating element and the internal liquid cooling heat-dissipation structure, and the two opposite surfaces of the insulating and heat conducting structure directly contact the heating element and the heat conducting sheet, respectively.

In an embodiment of the invention, the tank of the internal liquid cooling heat-dissipation structure further includes a temperature sensor disposed on a surface of the tank and employed to sense a temperature of the tank.

In an embodiment of the invention, the tank of the internal liquid cooling heat-dissipation structure further includes a LED module disposed on the surface of the tank and employed to indicate different colors according to levels of the temperature.

In an embodiment of the invention, the LED module is electrically connected to the circuit board through a connector.

In an embodiment of the invention, the power supply apparatus further includes at least one fan module, assembled in the case, electrically connected with the circuit board and employed to operate in different rotation speeds according to levels of the temperature.

In an embodiment of the invention, the internal liquid cooling heat-dissipation structure further includes a liquid cooling head, and the power supply apparatus further includes at least one external liquid cooling heat-dissipation structure disposed outside the case and including a heat sink, a cooling fan, a motor, a liquid cooling tank and an external pipe. The liquid cooling head is connected with the external pipe, the cooling fan is assembled to the heat sink, and the liquid cooling tank is connected with the motor. The external pipe is connected between the liquid cooling head and the liquid cooling tank, between the motor and the heat sink and between the heat sink and the liquid cooling head.

In an embodiment of the invention, the external liquid cooling heat-dissipation structure is connected with the internal liquid cooling heat-dissipation structure for form a loop. The working fluid circulates in the loop by the motor of the external liquid cooling heat-dissipation structure.

In an embodiment of the invention, the heating element is a passive device or a semiconductor device.

In an embodiment of the invention, a material of the heat conducting sheet includes metal.

In an embodiment of the invention, the working fluid includes pure water, deionized water, liquid metal or an organic fluorocarbon liquid.

Based on the above, in the design of the power supply apparatus of the invention, the internal liquid cooling heat-dissipation structure is disposed in the case and located in at least one of the manners which include being located between the case and the circuit board and being located between the case and the heating elements. The working fluid is adapted to be filled in the internal pipe, and the heat generated by the heating elements can be transmitted to the tank through the heat conducting sheet and be dissipated by the working fluid circulating in the internal pipe. In brief, the internal liquid cooling heat-dissipation structure of the invention can be adapted to various types of power supply apparatuses. The power supply apparatus of the invention can dissipate the heat in a liquid-cooling dissipation manner, which can achieve not only a favorable heat dissipation effect but also higher use safety and can avoid the occurrence of high noise.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic perspective diagram illustrating a power supply apparatus according to an embodiment of the invention.

FIG. 1B is a schematic side-view diagram illustrating the power supply apparatus depicted in FIG. 1A.

FIG. 1C is a schematic perspective exploded diagram illustrating an internal liquid cooling heat-dissipation structure of the power supply apparatus depicted in FIG. 1A.

FIG. 1D is a schematic perspective bottom-view diagram illustrating the internal liquid cooling heat-dissipation structure depicted in FIG. 1C.

FIG. 2 is a schematic side-view diagram illustrating a power supply apparatus according to another embodiment of the invention.

FIG. 3 is a schematic perspective diagram illustrating a power supply apparatus according to an embodiment of the invention.

FIG. 4 is a schematic diagram illustrating a liquid cooling system including the power supply apparatus depicted in FIG. 1A.

### DESCRIPTION OF EMBODIMENTS

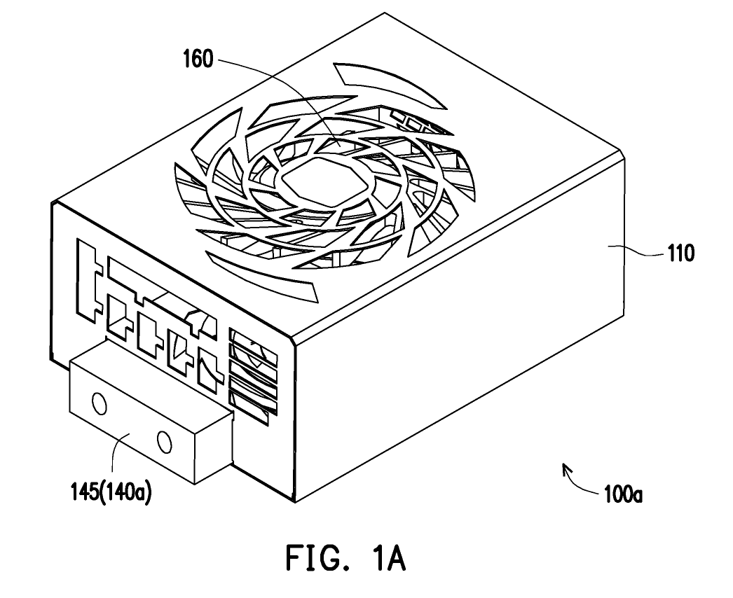

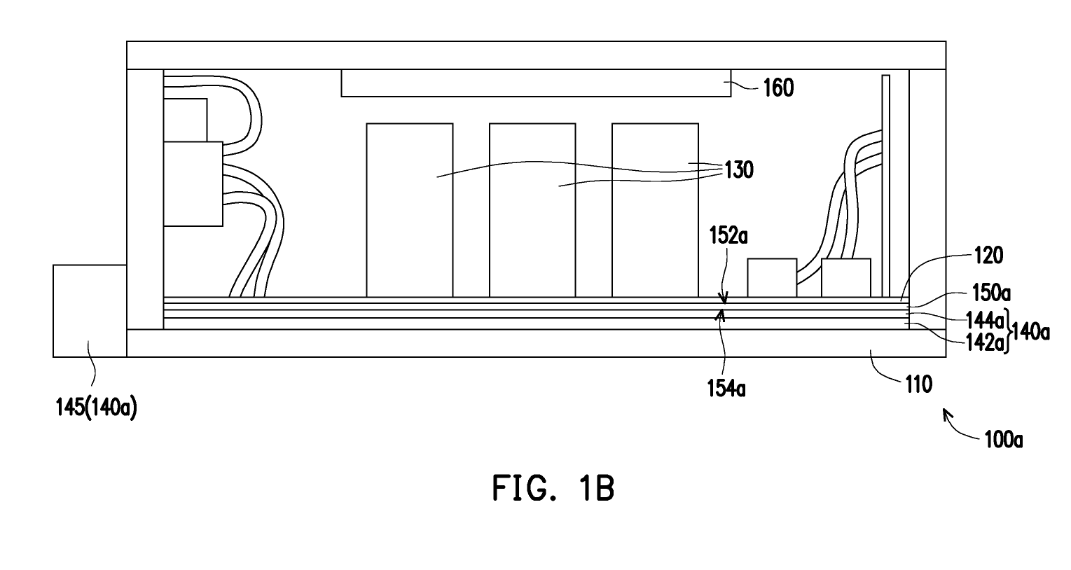

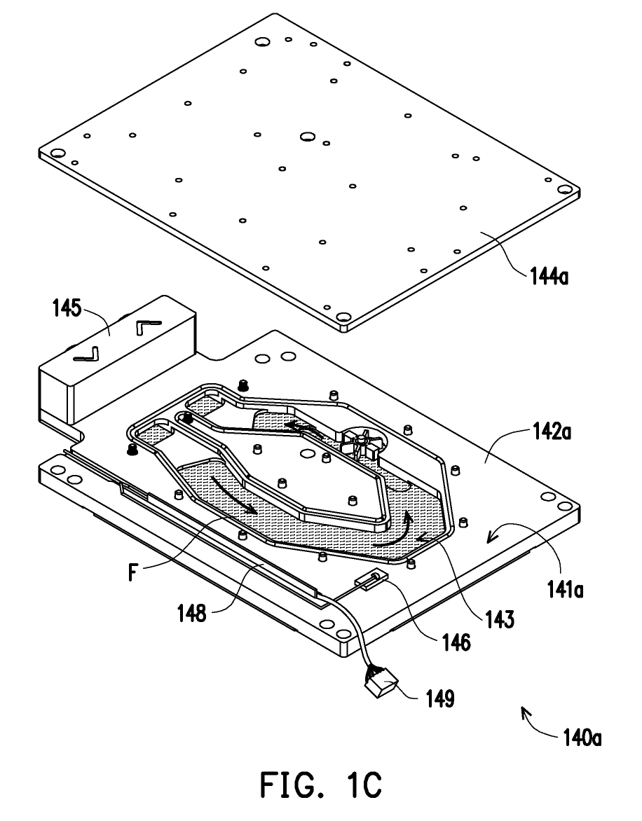

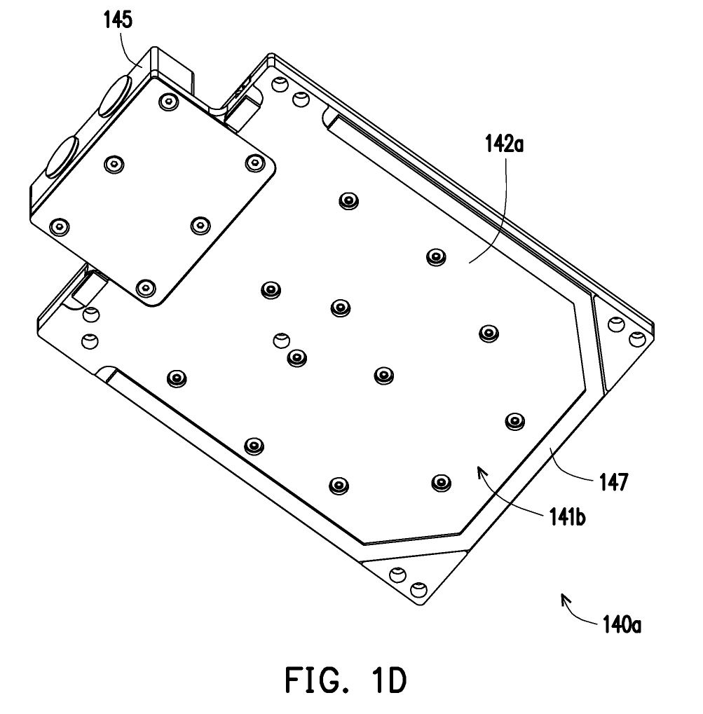

FIG. 1A is a schematic perspective diagram illustrating a power supply apparatus according to an embodiment of the invention. FIG. 1B is a schematic side-view diagram illustrating the power supply apparatus depicted in FIG. 1A. FIG. 1C is a schematic perspective exploded diagram illustrating an internal liquid cooling heat-dissipation structure of the power supply apparatus depicted in FIG. 1A. FIG. 1D is a schematic perspective bottom-view diagram illustrating the internal liquid cooling heat-dissipation structure depicted in FIG. 1C.

Referring first to FIG. 1A, FIG. 1B and FIG. 1C, a power supply apparatus 100a of the present embodiment includes a case 110, a circuit board 120, at least one heating element 130 (schematically illustrated as three heating elements 130 in FIG. 1B) and at least one internal liquid cooling heat-dissipation structure 140a (schematically illustrated as one internal liquid cooling heat-dissipation structure 140a in FIG. 1B). The circuit board 120 is disposed in the case 110, wherein the circuit board 110 has a component surface and a solder surface. The heating elements 130 are disposed in the case 110, located on the component surface of the circuit board 110 and electrically connected with the circuit board 120. The internal liquid cooling heat-dissipation structure 140a is disposed in the case 110 and located between the case 110 and the circuit board 120. The internal liquid cooling heat-dissipation structure 140a includes a tank 142a and a heat conducting sheet 144a. The tank 142a includes an internal pipe 143, wherein a working fluid F is adapted to be filled in the internal pipe 143. The heat conducting sheet 144a is assembled to the tank 142a, wherein the heat generated by the heating elements 130 is transmitted to the tank 142a through the heat conducting sheet 144a and is dissipated by the working fluid F circulating in the internal pipe 143.

Specifically, the heating elements 130 of the present embodiment are capacitors or transformers and certainly, may be other passive devices or other semiconductor devices, which are not limited herein. In addition, the working fluid F filled in the internal pipe 143 of the tank 142a may be, for example, pure water, deionized water, liquid metal or an organic fluorocarbon liquid. For instance, if the working fluid F is the pure water or the deionized water, due to water having a specific heat capacity which is much greater than that of the air or other liquids, which is about 4200 J/(kg·K), the water employed as a heat-dissipation medium has preferable thermal performance to the conventional systems using the air and fans. In addition, the heat conducting sheet 144a of the internal liquid cooling heat-dissipation structure 140a of the present embodiment is embodied as a copper sheet or any other metal sheet which transmits the heat generated by the heating elements 130 to the external of the power supply apparatus 100a by means of conduction.

As illustrated in FIG. 1C, the tank 142a of the internal liquid cooling heat-dissipation structure 140a of the present embodiment further includes a temperature sensor 146 disposed on a surface 141a of the tank 142a to sense a temperature of the tank 142a. Furthermore, the tank 142a of the internal liquid cooling heat-dissipation structure 140a further includes a light-emitting diode (LED) module 148 disposed on the surface 141a of the tank 142a and employed to indicate different colors according to levels of the temperature sensed by the temperature sensor 146. The LED module 148 may be electrically connected to the circuit board 120 through a connector 149, and the LED module 148 may be electrically connected to the circuit board 120 directly or indirectly through the connector 149, which is not particularly limited herein. In addition, referring to both FIG. 1C and FIG. 1D, the tank 142a of the internal liquid cooling heat-dissipation structure 140a of the present embodiment may further include a liquid cooling head 145 and a buffer bar 147. The liquid cooling head 145 is assembled to the tank 142a and employed to be connected with an external liquid cooling heat-dissipation structure (not shown), and the buffer bar 147 is disposed on a bottom surface 141b of the tank 142a and employed to buffer an impact force between two elements (e.g., the case 110 and the tank 142a).

In addition, the power supply apparatus 100a of the present embodiment further includes at least one insulating and heat conducting structure 150a disposed in the case 110 and located between the circuit board 120 and the internal liquid cooling heat-dissipation structure 140a, wherein the insulating and heat conducting structure 150a is capable of conducting the heat and transmitting the heat generated by the heating elements 130 to the internal liquid cooling heat-dissipation structure 140a. As illustrated in FIG. 1B, in the present embodiment, the internal liquid cooling heat-dissipation structure 140a is embodied as being located between the case 110 and the circuit board 120, the insulating and heat conducting structure 150a is located between the circuit board 120 and the internal liquid cooling heat-dissipation structure 140a, and two opposite surfaces 152a and 154a of the insulating and heat conducting structure 150a directly contact the solder surface of the circuit board 120 and the heat conducting sheet 144a, respectively. Namely, the insulating and heat conducting structure 150a may transmit the heat on the circuit board 120 to the internal liquid cooling heat-dissipation structure 140a, and the internal liquid cooling heat-dissipation structure 140a may dissipate the heat by the working fluid F circulating in the internal pipe 143, thereby effectively dissipating the heat. In addition, as the insulating and heat conducting structure 150a having an insulation characteristic may isolate the solder surface of the circuit board 120 from the heat conducting sheet 144a of the internal liquid cooling heat-dissipation structure 140a by the surface 152a of the insulating and heat conducting structure 150a contacting the solder surface of the circuit board 120. In this way, an arc discharge issue caused by the solder surface of the circuit board 120 contacting the heat conducting sheet 144a during the operation of the power supply apparatus 100a may be prevented. Namely, the insulating and heat conducting structure 150a of the invention has both thermal conduction and insulation characteristics and is capable of not only effectively conducting the heat of the circuit board 120 to the internal liquid cooling heat-dissipation structure 140a, but also preventing the arc discharge issue. Additionally, in the present embodiment, the disposition of the internal liquid cooling heat-dissipation structure 140a and the insulating and heat conducting structure 150a is not limited by the design of the circuit board 120 and the disposition of the elements in the case 110, and even though R&D personnel change the circuit design or increase/reduce the number of the elements, the internal liquid cooling heat-dissipation structure 140a does not have to be re-molded and may be adapted to various types of power supply apparatuses and thus, has preferable use flexibility.

Additionally, in order to further promote the heat dissipation effect of the power supply apparatus 100a, the power supply apparatus 100a of the present embodiment may further include at least one fan module 160 assembled in the case 110, electrically connected with the circuit board 120 and employed to operate in different rotation speeds according to levels of the temperature. As illustrated in FIG. 1A and FIG. 1B, the fan module 160 of the present embodiment is embodied as being disposed above the heating elements 130, but the invention is not limited thereto. In brief, the power supply apparatus 100a of the present embodiment is capable of achieving liquid-cooling dissipation in combination with fan-cooling dissipation. Namely, the heat may be dissipated not only by the working fluid F circulating in the internal pipe 143 of the internal liquid cooling heat-dissipation structure 140a, but also secondarily dissipated by the fan module 160, thereby enhancing the heat dissipation effect of the power supply apparatus 100a.

It is to be mentioned that the power supply apparatus 100a of the present embodiment is not limited to dissipating the heat simultaneously in the liquid-cooling dissipation manner and the fan-cooling dissipation manner. The heat power supply apparatus 100a may also dissipate the heat solely in the liquid-cooling dissipation manner. For example, the power supply apparatus 100a, after using the two types of dissipation, may turn off the fan module 160 for the fan-cooling dissipation through a circuit design in an occasion of a low load or less heat-dissipation demand. In this circumstance, the power supply apparatus 100a dissipates the heat solely in the liquid-cooling dissipation manner, thereby not only saving energy consumption but also achieving a completely mute effect.

An experiment example in a power condition where an input voltage is 99 VAC, and an output load is 1200 W is provided. The temperature of the heating elements of the present embodiment where the power supply apparatus 100a adopts the liquid-cooling dissipation manner is compared with the temperature of the heating elements of the conventional power supply apparatus adopting the fan-cooling dissipation manner. It can be learned from the experiment data listed in the below table.

| | Fan-cooling | Liquid-cooling |
|---|---|---|
| Heating element | dissipation | dissipation |
| EMI*-core-1 | 95.3° C. | 87.1° C. |
| EMI-core-2 | 73.8° C. | 71.6° C. |
| Bridge rectifier | 87.4° C. | 83.9° C. |
| PFC**-Inductor | 105.9° C. | 100.4° C. |
| PFC-Switch | 102.2° C. | 95.8° C. |
| PFC-Diode | 90.9° C. | 85° C. |
| Isolation transformer-1 | 106.1° C. | 97° C. |
| Isolation transformer-2 | 100.5° C. | 90.8° C. |
| Full-bridge switch | 78.5° C. | 73.8° C. |

*EMI stands for electromagnetic wave interference.
**PFC stands for power factor corrector.

By being compared with the heating elements (e.g., EMI-cores or isolation transformers) in the conventional power supply apparatus, the heating elements 130 (e.g., EMI-cores or isolation transformers) in the power supply apparatus 100a of the present embodiment have lower temperatures, and the temperatures of the heating elements may be reduced by 2° C. to 9° C. Namely, in the same condition, the power supply apparatus 100a of the present embodiment, compared with the conventional power supply apparatus adopting the fan-cooling dissipation manner, may achieve not only a preferable heat dissipation effect, but also preventing the occurrence of high noise.

It should be noted that the embodiments provided below use the reference numerals and part of the content of the embodiment above, where the same or similar elements are represented by using the same reference numerals and the description related to the same technical content is omitted. The description related to the omitted part may refer to that of the embodiment above and will not be repeated hereinafter.

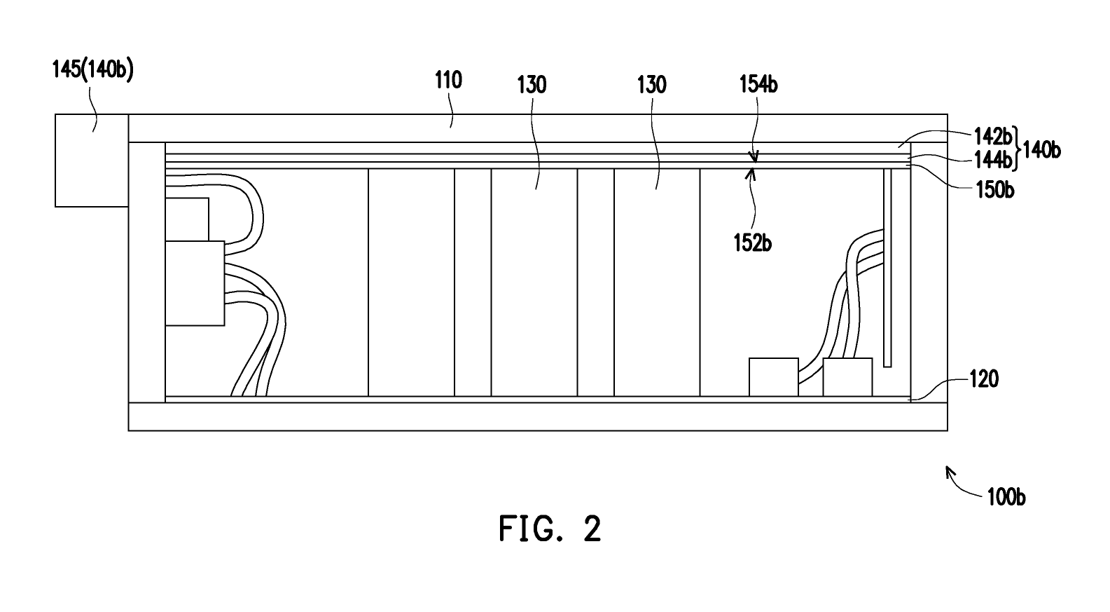

FIG. 2 is a schematic side-view diagram illustrating a power supply apparatus according to another embodiment of the invention. Referring to both FIG. 1B and FIG. 2, a power supply apparatus 100b of the present embodiment is similar to the power supply apparatus 100a illustrated in FIG. 1B, and the difference between the two includes: no fan module 160 is disposed in the power supply apparatus 100b of the present embodiment (or the fan module 160 may be disposed on a side opposite to the liquid cooling head 145 in the case 110, which is not limited herein), an internal liquid cooling heat-dissipation structure 140b is disposed between the case 110 and the heating elements 130, an insulating and heat conducting structure 150b is located between the heating elements 130 and the internal liquid cooling heat-dissipation structure 140b, and two opposite surfaces 152b and 154b of the insulating and heat conducting structure 150b directly contact the heating elements 130 and a heat conducting sheet 144b, respectively. Namely, the heat generated by the heating elements 130 is transmitted to the heat conducting sheet 144b of the internal liquid cooling heat-dissipation structure 140b through the insulating and heat conducting structure 150b and is dissipated by the working fluid F circulating in the internal pipe 143 of a tank 142b, thereby effectively dissipating the heat. Thus, in the present embodiment, the heat generated by the heating elements 130 is conducted by using the insulating and heat conducting structure 150b, instead of being conducted by using a liquid-cooling dissipation metal pipe where a plurality of the heating elements 130 have to be filled with glue in advance.

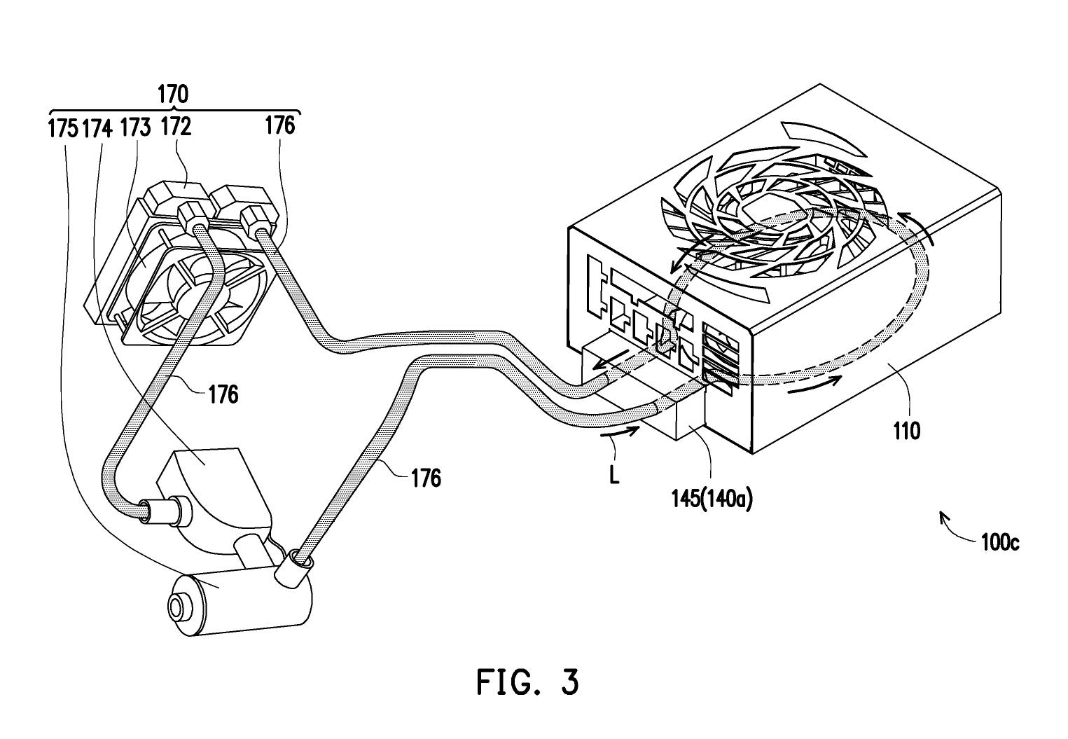

FIG. 3 is a schematic perspective diagram illustrating a power supply apparatus according to an embodiment of the invention. For descriptive convenience, a part of the elements (e.g., the fan module) are omitted in FIG. 3. Referring to both FIG. 1B and FIG. 3, a power supply apparatus 100c of the present embodiment is similar to the power supply apparatus 100a illustrated in FIG. 1B, and the difference between the two includes: the power supply apparatus 100c of the present embodiment further includes at least one external liquid cooling heat-dissipation structure 170 disposed outside the case 110 and including a heat sink 172, a cooling fan 173, a motor 174, a liquid cooling tank 175 and an external pipe 176. The liquid cooling head 145 of the internal liquid cooling heat-dissipation structure 140a is connected to the external pipe 176 of the external liquid cooling heat-dissipation structure 170, the cooling fan 173 is assembled to the heat sink 172, and the liquid cooling tank 175 is connected to the motor 174. The external pipe 176 is connected between the liquid cooling head 145 of the internal liquid cooling heat-dissipation structure 140a and the liquid cooling tank 175, between the motor 174 and the heat sink 172 and between the heat sink 172 and the liquid cooling head 145 of the internal liquid cooling heat-dissipation structure 140a. The external liquid cooling heat-dissipation structure 170 is connected to the internal liquid cooling heat-dissipation structure 140a to form a loop L, and the working fluid F circulates in the loop L by the motor 174 of the external liquid cooling heat-dissipation structure 170, thereby reducing the temperature of the power supply apparatus 100c.

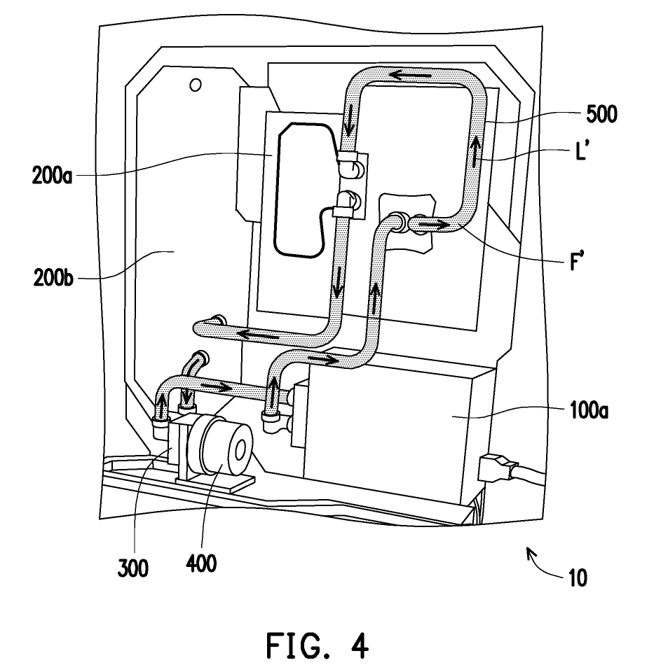

FIG. 4 is a schematic diagram illustrating a liquid cooling system including the power supply apparatus depicted in FIG. 1A. A liquid cooling system 10 of the present embodiment, in addition to the power supply apparatus 100a described above, also includes a liquid cooling heat-dissipation structure 200a disposed corresponding to a position of a graphics card in a computer host and a liquid cooling heat-dissipation structure 200b disposed corresponding to a computer motherboard. The power supply apparatus 100a and the liquid cooling heat-dissipation structures 200a and 200b are connected through the external pipe 500. The liquid cooling tank 300 is connected with the motor 400, i.e., the power supply apparatus 100a, the graphics card and the motherboard share the external liquid cooling heat-dissipation structure (which includes the liquid cooling tank 300, the heat sink and the motor 400), the external pipe 500 is connected in series with the power supply apparatus 100a and the liquid cooling heat-dissipation structures 200a and 200b to form a loop L′, and a working fluid F′ circulates in the loop L′, thereby reducing a temperature of the liquid cooling system 10.

Additionally, in another embodiment which is not shown, the power supply apparatus may also include a plurality of internal liquid cooling heat-dissipation structures, for example, two internal liquid cooling heat-dissipation structures, where one of them is disposed between the case and the circuit board, and the other is disposed between the case and the heating element, which also falls within the scope to be protected by the invention. A person skilled in the art may achieve the desired technical effect with reference to the descriptions related to the embodiments set forth above and according to actual demands.

In light of the foregoing, in the design of the power supply apparatus of the invention, the internal liquid cooling heat-dissipation structure is disposed in the case and located in one of the manners which include being located in between the case and the circuit board and being located between the case and the heating elements, wherein the working fluid is adapted to be filled in the internal pipe, and the heat generated by the heating elements is transmitted to the tank through the heat conducting sheet and is dissipated by the working fluid circulating in the internal pipe. In brief, the internal liquid cooling heat-dissipation structure of the invention can be applied in various types of power supply apparatuses, and the power supply apparatus of the invention can achieve heat-dissipation in the liquid-cooling dissipation manner. In this way, not only a favorable heat dissipation effect, but also higher use safety can be obtained, and the occurrence of high noise can be prevented.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A power supply apparatus, comprising:
a case;
a circuit board, disposed in the case;
at least one heating element, disposed in the case and electrically connected to the circuit board; and
at least one internal liquid cooling heat-dissipation structure, disposed in the case and located in at least one of manners which comprise being located between the case and the circuit board and being between the case and the heating element, wherein the internal liquid cooling heat-dissipation structure comprises:
a tank, comprising an internal pipe, wherein a working fluid is adapted to be filled in the internal pipe; and
a heat conducting sheet, assembled to the tank, wherein the heat generated by the heat element is transmitted to the tank through the heat conducting sheet and is dissipated by the working fluid circulating in the internal pipe.

2. The power supply apparatus according to claim 1, further comprising:
at least one insulating and heat conducting structure, disposed in the case and located in at least one of manners which comprise being located between the circuit board and the internal liquid cooling heat-dissipation structure and being located between the heating element and the internal liquid cooling heat-dissipation structure.

3. The power supply apparatus according to claim 2, wherein the internal liquid cooling heat-dissipation structure is located between the case and the circuit board, the insulating and heat conducting structure is located between the circuit board and the internal liquid cooling heat-dissipation structure, and two opposite surfaces of the insulating and heat conducting structure directly contact the circuit board and heat conducting sheet, respectively.

4. The power supply apparatus according to claim 2, wherein the internal liquid cooling heat-dissipation structure is located between the case and the heating element, the insulating and heat conducting structure is located between the heating element and the internal liquid cooling heat-dissipation structure, and two opposite surfaces of the insulating and heat conducting structure directly contact the heating element and the heat conducting sheet, respectively.

5. The power supply apparatus according to claim 1, wherein the tank of the internal liquid cooling heat-dissipation structure further comprises a temperature sensor disposed on a surface of the tank and employed to sense a temperature of the tank.

6. The power supply apparatus according to claim 5, wherein the tank of the internal liquid cooling heat-dissipation structure further comprises a light-emitting diode (LED) module disposed on the surface of the tank and employed to indicate different colors according to levels of the temperature.

7. The power supply apparatus according to claim 6, wherein the LED module is electrically connected to the circuit board through a connector.

8. The power supply apparatus according to claim 5, further comprising:
at least one fan module, assembled in the case, electrically connected with the circuit board and employed to operate in different rotation speeds according to levels of the temperature.

9. The power supply apparatus according to claim 1, wherein the internal liquid cooling heat-dissipation structure further comprises a liquid cooling head, and the power supply apparatus further comprises:
at least one external liquid cooling heat-dissipation structure, disposed outside the case and comprising a heat sink, a cooling fan, a motor, a liquid cooling tank and an external pipe, wherein the liquid cooling head is connected with the external pipe, the cooling fan is assembled to the heat sink, the liquid cooling tank is connected with the motor, and the external pipe is connected between the liquid cooling head and the liquid cooling tank, between the motor and the heat sink and between the heat sink and the liquid cooling head.

10. The power supply apparatus according to claim 9, wherein the external liquid cooling heat-dissipation structure is connected with the internal liquid cooling heat-dissipation structure for form a loop, the working fluid circulates in the loop by the motor of the external liquid cooling heat-dissipation structure.

11. The power supply apparatus according to claim 1, wherein the heating element is a passive device or a semiconductor device.

12. The power supply apparatus according to claim 1, wherein a material of the heat conducting sheet comprises metal.

13. The power supply apparatus according to claim 1, wherein the working fluid comprises pure water, deionized water, liquid metal or an organic fluorocarbon liquid.
